(19) United States
(12) Patent Application Publication
(10) Pub. No.: US 2013/0181279 A1
(43) Pub. Date: Jul. 18, 2013

(54) SONOS STRUCTURE AND MANUFACTURING METHOD THEREOF

(71) Applicant: Shanghai Huali Microelectronics Corporation, Shanghai (CN)

(72) Inventors: Zhi TIAN, Shanghai (CN); Xinyun XIE, Shanghai (CN)

(73) Assignee: SHANGHAI HUALI MICROELECTRONICS CORPORATION, Shanghai (CN)

(21) Appl. No.: 13/721,068

(22) Filed: Dec. 20, 2012

(30) Foreign Application Priority Data
Jan. 12, 2012 (CN) 201210009215.0

(51) Int. Cl. H01L 29/792; H01L 21/28

(52) U.S. Cl. CPC H01L 29/792; H01L 21/28282
USPC 257/324; 438/591

(57) ABSTRACT

The invention provides an SONOS structure and a manufacturing method thereof The manufacturing method comprises: forming a tunneling oxide layer on a substrate; depositing a Si-rich silicon nitride layer above the tunneling oxide layer, wherein the Si/N content ratio of the Si-rich silicon nitride layer is constant; depositing a graded silicon nitride layer having graded silicon content above the Si-rich silicon nitride layer; and depositing a blocking oxide layer; wherein the silicon content of the graded silicon nitride layer is reduced in the direction from the Si-rich silicon nitride layer to the blocking oxide layer. According to the present invention, the Si-rich silicon nitride layer provides shallower trapping levels, which is beneficial to trap the charges and improve the programming and erasing speed. Furthermore, the charge retention time increases due to the constrained charges in the deep trapping levels, thus the reliability of the device enhances.

### CROSS-REFERENCE TO RELATED APPLICATION

This application claims the priority benefit of China application serial NO. 201210009215.0, filed Jan. 12, 2012. All disclosure of the China application is incorporated herein as reference.

### FIELD OF THE INVENTION

The present invention relates to the field of semiconductor manufacturing technology, and more particularly to an SONOS structure and a manufacturing method thereof.

### BACKGROUND OF THE INVENTION

With the miniaturization and microminiaturization of the semiconductor storage devices, it is difficult for the conventional floating-gate storage structure to adapt to the future development due to the excessive laminated thickness of the gate and the high requirements of the insulating property of the tunneling oxide layer. Recently, the nonvolatile memory storage of the SONOS (Polysilicon-Oxide-Nitride-Oxide-Silicon) structure with excellent insulating property is getting attention again due to the advantages of high charge-trapping ability compared to the conventional floating-gate storage device, the property of easy miniaturization and process simplicity.

Kuo-Hong Wu (SONOS device with tapered bandgap nitride layer, IEEE transcation on electron devices, Vol. 52, No. 5, May 2005. Kuo-Hong Wu, etc) proposed an SONOS device with a unique tapered bandgap structure. A varying Si—N composition ratio in a modified silicon nitride layer is obtained by controlling the reaction gas flow-rate ratio, wherein the oxide nitride close to the tunneling oxide layer 2 contains high silicon content (as shown in FIG. 1), while the oxide nitride close to the block oxide layer 3 contains high nitrogen content (as shown in the bottom part of the silicon nitride layer 5 with a varying Si/N ratio in FIG. 1). The Si/N ratio is gradually changing, and a tapered bandgap corresponding to the Si/N ratio is formed in the silicon nitride layer 5 as shown in FIG. 1. A test for the standard silicon nitride layer and silicon nitride layer 5 with tapered bandgap is performed under optimal asymmetric P/E (program/erase) operating voltage. As a result, devices having silicon nitride layers 5 with tapered bandgap exhibit larger threshold voltage shifts and wider storage windows. Furthermore, through the test of the endurance ability of the new device, no endurance degradation is observed even after 10⁶ cycles of the P/E operation. And based on an extrapolation method, the tapered bandgap structure still exhibits a window of 1.3V after ten years due to the large threshold voltage shift, even though the charge retention ability of the device at room temperature has not be improved. However, the tapered bandgap structure has less shallow trapping level, which results in the slow initial programming and erasing speed.

The China application (application serial No. 200910057131.2) and CHIEN H C et al. (Two-bits SONOS type flash using a band engineering in the nitride layer. Microelectronic Engineering, 2005, 80 (17):256-259. CHIEN H C et al) also disclose an improved tapered structure (olive band structure) for the improvements of the SONOS bandgap structure. Wherein by controlling the reaction gas flow-rate ratio during the LPCVD process, a bandgap structure of the SONOS device as shown in FIG. 2 is formed in which the part of the silicon nitride layer close to the tunneling oxide layer 2 is Si-rich and the part of the silicon nitride layer close to the blocking oxide layer is N-rich. From the bandgap diagram of FIG. 2, the barrier height at the interface between the silicon nitride layer and the adjacent oxide layer is larger than the typical barrier height. Therefore the trapped charges are not easy to escape from the silicon nitride layer and data retention is improved. Besides, the injected charges from the substrate fall into shallow trapping sites at first and then migrate to adjacent deeper trapping sites. Consequently the charge-trapping efficiency of the non-uniform silicon nitride layer is better than that of a uniform silicon nitride layer. An examination of the new device property shows that the threshold voltage shifts and P/E operation window of the new devices are larger than that of a standard device using silicon nitride layer or a device using silicon nitride layer with trapped bandgap structure. The endurance ability and the charge retention ability at room temperature of the new devices are similar to that of the device using silicon nitride layer with trapped bandgap structure and better than the standard device having silicon nitride layer. However, the structure still cannot provide improvements in the initial programming and erasing speed.

### SUMMARY OF THE INVENTION

Accordingly, at least one objective of the present invention is to provide improvements for the programming and erasing speed of the SONOS devices.

To achieve these and other advantages and in accordance with the objective of the invention, as embodied and broadly described herein, the present invention is configured as follows.

In accordance with the first aspect of the present invention, there is provided a method of manufacturing an SONOS structure comprising: forming a tunneling oxide layer on a substrate; depositing a Si-rich silicon nitride layer above the tunneling oxide layer, wherein the Si/N content ratio of the Si-rich silicon nitride layer is constant; depositing a graded silicon nitride layer having graded silicon content above the Si-rich silicon nitride layer; and depositing a blocking oxide layer above the graded silicon nitride layer; wherein the silicon content of the graded silicon nitride layer is reduced in the direction from the Si-rich silicon nitride layer to the blocking oxide layer.

Preferably, the method of manufacturing an SONOS structure further comprises forming a gate electrode on the blocking oxide layer.

Preferably, the step of depositing the Si-rich silicon nitride layer on the tunneling oxide layer is performed under the condition of a SiH₂Cl₂/NH₃ gas flow-rate ratio of 2.07.

Preferably, in the step of depositing the graded silicon nitride layer on the Si-rich silicon nitride layer, the SiH₂Cl₂/NH₃ gas flow-rate ratio is reduced with time, and finally reduced to 0.1.

Preferably, the thickness of the Si-rich silicon nitride layer is from 1/10 to ½ of the thickness of the graded silicon nitride layer.

In accordance with the second aspect of the present invention, there is provided an SONOS structure comprising a tunneling oxide layer formed on a substrate, a Si-rich silicon nitride layer formed on the tunneling oxide layer, a graded silicon nitride layer having graded silicon content formed on the Si-rich silicon nitride layer, a blocking oxide layer formed on the graded silicon nitride layer, and a gate electrode formed on the blocking oxide layer; wherein the Si/N content ratio of the Si-rich silicon nitride layer is constant, and the silicon content of the graded silicon nitride layer is reduced in the direction from the Si-rich silicon nitride layer to the blocking oxide layer.

Preferably, the thickness of the Si-rich silicon nitride layer is from 1/10 to ½ of the thickness of the graded silicon nitride layer.

According to the present invention, the Si-rich nitride layer and the graded silicon nitride layer are used to improve the structure of the silicon nitride layer in the SONOS. Since the Si-rich silicon nitride layer has shallower trapping levels, the charge-trapping efficiency increases and the programming and erasing speed enhances. Furthermore, the substrate-injected charges can be transferred from the shallow trapping levels to the deep trapping levels of the graded silicon nitride layer through lateral hopping, which not only make the deep trapping levels receive more charges but also enhance the reliability of the device since the charge retention time increases due to the charges being constrained in the deep trapping levels of the N-rich part of the graded silicon nitride layer. In addition, this SONOS structure not only improves the initial programming and erasing speed of the graded silicon nitride layer, but also can realize various programming and erasing speeds by adjusting the thickness ratio of the Si-rich silicon nitride layer and the graded silicon nitride layer, which provides a wide application scope.

### BRIEF DESCRIPTION OF THE DRAWINGS

The SONOS structure and manufacturing method thereof of the present invention will be elucidated by reference to the following embodiments and the accompanying drawings, in which:

FIG. 1 is a cross-sectional view of a conventional SONOS structure having a silicon nitride layer with tapered bandgap;

FIG. 2 is a band diagram in a conventional modified SONOS structure having a graded silicon nitride layer;

FIG. 3 is a cross-sectional view of the SONOS structure having a Si-rich silicon nitride layer and a graded silicon nitride layer in an embodiment of the present invention;

FIG. 4 is a band diagram in the SONOS structure having the Si-rich silicon nitride layer and the graded silicon nitride layer in an embodiment of the present invention.

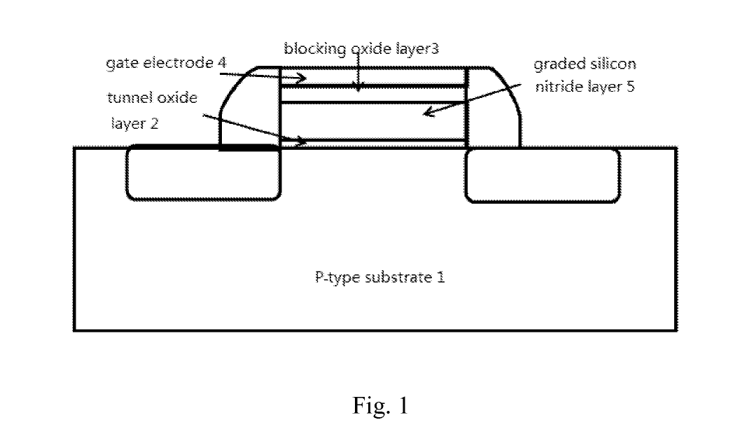

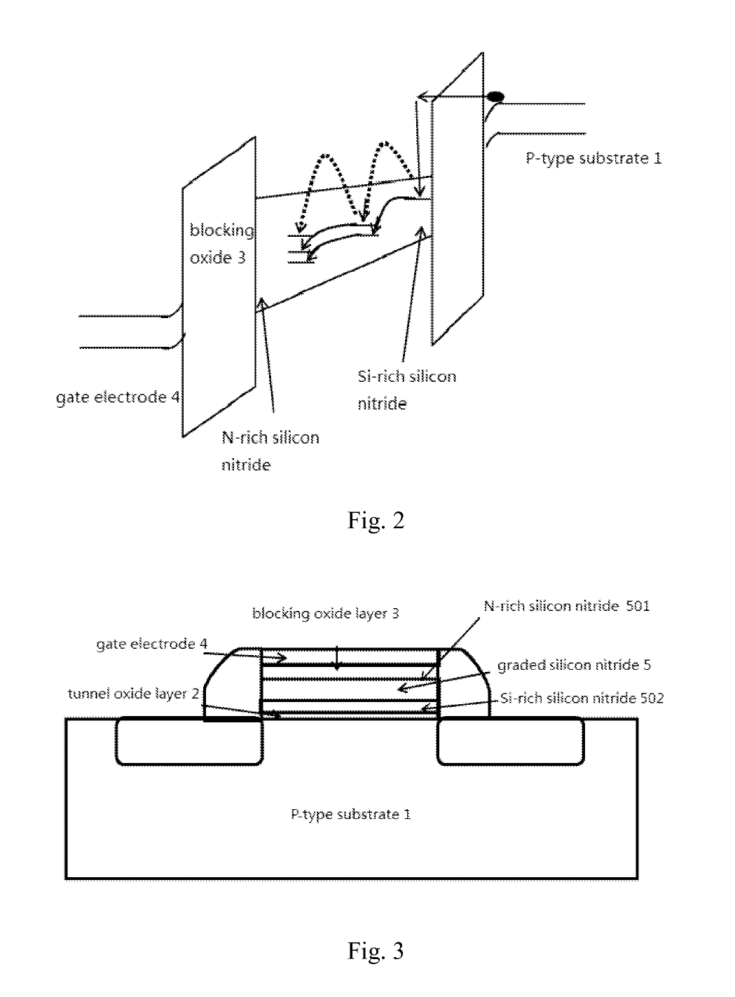

### DETAILED DESCRIPTION OF THE EMBODIMENTS

The SONOS structure and manufacturing method of the SONOS structure of the present invention will be described in further details hereinafter with respect to the embodiments and the accompanying figures, wherein like reference numerals are used throughout the figures to designate similar or equivalent element, the figures are not drawn to scale and they are provided merely to illustrate the invention instead of limiting the scope of the present invention.

FIG. 3 is a cross-sectional view showing the SONOS structure having a Si-rich silicon nitride layer and a graded silicon nitride layer in one embodiment of the present invention.

Referring to FIG. 3, during the manufacturing process of the SONOS structure, a tunneling oxide layer 2 is formed on the P-type substrate 1 at first; then a Si-rich silicon nitride layer 502 is deposited above the tunneling oxide layer 2 and a graded silicon nitride layer 5 with graded silicon content is deposited above the Si-rich silicon nitride layer 502, wherein the top portion of the graded silicon nitride layer 5 forms an N-rich silicon nitride layer 501. The silicon content of the graded silicon nitride layer 5 is reduced in the direction from the Si-rich silicon nitride layer 502 to the N-rich silicon nitride layer 501.

The Si-rich silicon nitride layer 502 and the graded silicon nitride layer 5 as shown in FIG. 3 can have different silicon and nitrogen content by controlling the composition ratio or flow-rate ratio of the silicon-containing gas and the nitrogen-containing gas. Such structures can be achieved based on the conventional method of silicon nitride deposition.

For example, the SONOS structure in the embodiment is applied in a device having an SONOS gate structure. During the formation of the SONOS structure, a Si-rich silicon nitride layer 502 is deposited by adjusting SiH₂Cl₂/NH₃ gas flow-rate ratio to 2.07. Thus the Si/N ratio is maintained constant in the Si-rich silicon nitride layer 502.

Thereafter, a graded silicon nitride layer 5 with graded silicon content is deposited above the Si-rich silicon nitride layer 502, in the meanwhile the SiH₂Cl₂/NH₃ gas flow-rate ratio decrease with time. Preferably, when the top part of the graded silicon nitride layer 5 forms an N-rich silicon nitride layer 501, the SiH₂Cl₂/NH₃ gas flow-rate ratio decreases to 0.1. In other words, the SiH₂Cl₂/NH₃ gas flow-rate ratio decreases with time during the deposition of the graded silicon nitride layer 5 above the Si-rich silicon nitride layer 502, and finally decreases to 0.1.

These silicon nitride layers can have different silicon and nitrogen content by controlling the composition ratio or flow-rate ratio of the silicon-containing gas and the nitrogen-containing gas.

Moreover, a blocking oxide layer 3 is deposited above the silicon nitride layer with graded silicon 5 after the formation of the N-rich silicon nitride layer 501. At last, a gate electrode 4 is formed on the blocking oxide layer 3.

In accordance with such silicon nitride layer structure, shallower trapping levels can be formed adjacent to the substrate.

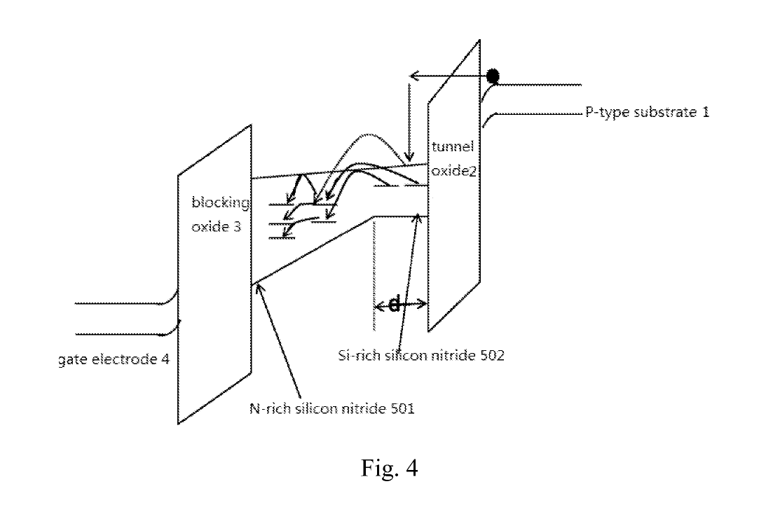

Referring to FIG. 4, which is a band diagram of the SONOS structure in an embodiment, in the SONOS structure having a Si-rich silicon nitride layer 502 of “d” thickness and a graded silicon nitride layer with graded silicon 5 deposited on the Si-rich silicon nitride layer 502, lot of the shallow trapping levels in the Si-rich silicon nitride layer 502 can trap much more charges, which increases the initial programming speed. When the charges reach a certain amount, the charges injected from the substrate 1 fall into the shallow trapping levels and then migrate into deeper trapping levels through lateral hopping. In the erase operation, the charges in the deeper trapping levels gradually migrate to shallower trapping levels and finally reach the shallow trapping levels of the Si-rich silicon nitride layer 502. Then the gathered charges in the shallow trapping levels of the Si-rich silicon nitride layer 502 can fall into the substrate 1 easily, which provides a faster erasing speed of the SONOS structure compared with the conventional SONOS structure with the graded silicon nitride layer 5 only.

Preferably, the initial programming speed and the reliability of the devices can be regulated by adjusting the thickness ratio of the Si-rich silicon nitride layer 502 and the graded silicon nitride layer 5 so as to provide more flexibility for different devices.

According to the manufacturing method mentioned above, an SONOS structure is formed. The SONOS structure comprises a tunneling oxide layer 2 deposited above a P-type substrate 1, a Si-rich silicon nitride layer 502 deposited above the tunneling oxide layer 2, a silicon nitride layer with graded silicon content 5 deposited above the Si-rich silicon nitride layer 502, a blocking oxide layer 3 deposited above the silicon nitride layer with graded silicon content 5, and a gate electrode 4 formed above the blocking oxide layer 3.

Wherein, the Si/N content ratio of the Si-rich silicon nitride layer 502 is maintained constant in the thickness “d”.

The silicon content of the silicon nitride layer with graded silicon content 5 is reduced in the direction from the Si-rich silicon nitride layer 502 to the blocking oxide layer 3. The top part of the silicon nitride layer with graded silicon content 5 adjacent to the surface of the blocking oxide layer 3 forms an N-rich silicon nitride layer 501.

In a preferred embodiment, the thickness of the Si-rich silicon nitride layer 502 is from 1/10 to ½ of the thickness of the silicon nitride layer with graded silicon content 5.

According to the SONOS structure of the present invention, a uniform Si-rich silicon nitride layer 502 is introduced below the silicon nitride layer with graded silicon content 5 to provide more shallow trapping levels, so as to store charges from the substrate faster and improve the initial programming speed of the SONOS devices. In the erase operation, charges from the deep trapping levels can be neutralized faster by the pluralities of the shallow trapping levels, which enhance the erasing speed of the SONOS devices.

In summary, according to the embodiment of present invention, the SONOS structure comprises a silicon nitride layer structure in which a Si-rich silicon nitride layer 502 and a silicon nitride layer with graded silicon content 5 are formed. Since the Si-rich silicon nitride layer 502 has shallower trapping levels, the charges can be trapped more easily and the programming and erasing speed can be increased. Besides, the deep trapping levels of the graded silicon nitride layer 5 can receive charges lateral hopped from the shallow tapping levels, which not only obtains more charges but also enhances the reliability of the device since the charge retention time increases due to the charges being constrained in the deep trapping levels of the N-rich portion of the graded silicon nitride layer 501. In addition, the SONOS structure not only improves the initial programming and erasing speed, but also realizes various programming and erasing speeds by adjusting the thickness ratio of the Si-rich silicon nitride layer 502 and the graded silicon nitride layer 5, which can provide a wider application scope. Note that although the SONOS structure is formed on a P-type substrate 1 in the embodiment, an N-type substrate can also be applied.

Although the present invention has been disclosed as above with respect to the preferred embodiments, they should not be constrained to the present invention. Various modifications and variations can be made by the ordinary skilled in the art without departing the spirit and scope of the present invention. Therefore, the protection scope of the present invention should be defined by the appended claims.

1. A method of manufacturing an SONOS structure comprising the following steps:
forming a tunneling oxide layer on a substrate;
depositing a Si-rich nitride layer above the tunneling oxide layer, wherein the Si/N content ratio of the Si-rich silicon nitride layer is constant;
depositing a graded silicon nitride layer having graded silicon content above the Si-rich silicon nitride layer;
depositing a blocking oxide layer above the graded silicon nitride layer; wherein
the silicon content of the graded silicon nitride layer is reduced in the direction from the Si-rich silicon nitride layer to the blocking oxide layer.

2. The method according to claim 1, further comprising forming a gate electrode on the blocking oxide layer.

3. The method according to claim 1, wherein the step of depositing the Si-rich silicon nitride layer on the tunneling oxide layer is performed under the condition of a SiH₂Cl₂/NH₃ gas flow-rate ratio of 2.07.

4. The method according to claim 1, wherein in the step of depositing the graded silicon nitride layer on the Si-rich silicon nitride layer, the SiH₂Cl₂/NH₃ gas flow-rate ratio is reduced with time, and finally reduced to 0.1.

5. The method according to claim 1, wherein the thickness of the Si-rich silicon nitride layer is from 1/10 to ½ of the thickness of the graded silicon nitride layer.

6. An SONOS structure comprising:
a tunneling oxide layer formed on a substrate, a Si-rich silicon nitride layer formed on the tunneling oxide layer, a graded silicon nitride layer having graded silicon content formed on the Si-rich silicon nitride layer, a blocking oxide layer formed on the graded silicon nitride layer, and a gate electrode formed on the blocking oxide layer; wherein the Si/N content ratio of the Si-rich silicon nitride layer is constant, and the silicon content of the graded silicon nitride layer is reduced in the direction from the Si-rich silicon nitride layer to the blocking oxide layer.

7. The SONOS structure according to claim 6, wherein the thickness of the Si-rich silicon nitride layer is from 1/10 to ½ of the thickness of the graded silicon nitride layer.
